(19) United States
(12) Patent Application Publication
(10) Pub. No.: US 2026/0305404 A1
(43) Pub. Date: Oct. 1, 2026

(54) PACKAGE-ON-PACKAGE DESIGN FOR IMPROVED MEMORY INTERCONNECT AND THERMAL MANAGEMENT IN SEMICONDUCTOR DEVICES

(71) Applicant: QUALCOMM Incorporated, San Diego, CA (US)

(72) Inventors: Jungwon SUH, San Diego, CA (US); Bernie YANG, San Diego, CA (US); Aniket PATIL, San Diego, CA (US)

(21) Appl. No.: 19/090,188

(22) Filed: Mar. 25, 2025

(51) Int. Cl. H01L 23/538; H01L 23/00; H01L 23/36; H01L 23/498; H01L 25/16; H10B 80/00

(52) U.S. Cl. CPC H10W 70/65; H10W 70/611; H10W 90/00; H10W 90/401; H10W 90/701; H10B 80/00; H10W 40/10; H10W 90/754

(57) ABSTRACT

A package-on-package (PoP) semiconductor device has an asymmetrically placed interface interconnect for connecting a top package to a bottom package. The interface interconnect can include a ball-out layout that is concentrated on one lateral side of the top package and/or bottom package. The PoP semiconductor device can include a heat slug on the bottom package to provide improved thermal management. The PoP semiconductor device can optimize interface interconnect routing, enhance thermal management, and achieve a more competitive form factor.

### TECHNICAL FIELD

The technology discussed below relates generally to semiconductor packaging, and more particularly, to package-on-package designs for semiconductor packaging.

### INTRODUCTION

Package-on-package (PoP) designs are widely used in semiconductor devices, particularly in mobile and compact electronic systems, due to their ability to integrate multiple functional components, such as a system-on-chip (SoC) and memory, into a single package. In some examples, a PoP configuration includes a stacking of a memory package on top of a logic or processor package (e.g., a SoC), with interconnects between the packages provided by solder balls or similar means. In some examples, the memory package may include dynamic random-access memory (DRAM) or low-power double data rate (LPDDR) memory. These designs can offer significant space-saving over side-by-side packaging.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a form as a prelude to the more detailed description that is presented later.

A package-on-package (PoP) semiconductor device has an asymmetrically placed interface interconnect, in particular a memory interface interconnect, for connecting a first package, in particular a memory package, to a second package, in particular a processor package. The interface interconnect can include a ball-out layout that is concentrated on one lateral side of the first package and/or second package. The PoP semiconductor device can include a heat slug on the processor package to provide improved thermal management. The PoP semiconductor device can optimize memory interface routing, enhance thermal management, and achieve a more competitive form factor.

One aspect of the disclosure provides a package-on-package (PoP) semiconductor device. The PoP semiconductor device includes a bottom package that includes a first die, for example a system-on-chip (SoC) die. The PoP semiconductor device further includes a top package positioned on the bottom package, the top package including one or more second dies, for example one or more memory dies. The PoP semiconductor device further includes an interconnect structure including a ball-out layout configured to connect the one or more first dies to the second die, wherein the ball-out layout is an asymmetrical ball-out layout that is asymmetric with respect to a mirror axis of at least one of the top package or the bottom package.

One aspect of the disclosure provides a semiconductor device. The semiconductor device includes a top package including one or more first dies,. The semiconductor device further includes a bottom package including a second die. The semiconductor device further includes an interconnect structure configured to connect the one or more first dies and the second die. The interconnect structure is asymmetrically placed on at least one of the bottom package or the second die.

One aspect of the disclosure provides a method for configuring a package-on-package (PoP) semiconductor device. The method provides a bottom package that includes a first die. The method further provides a top package positioned on the bottom package, the top package including one or more second dies. The method further provides an interconnect structure configured to connect the one or more second dies to the first die. The interconnect structure is an asymmetric interconnect structure that is asymmetric with respect to a mirror axis of at least one of the top package or the bottom package.

One aspect of the disclosure provides a method of configuring a semiconductor device. The method provides a top package including one or more first dies. The method provides a bottom package including a second die. The method further provides an interconnect structure configured to connect the one or more first dies and the second die, wherein the interconnect structure is asymmetrically placed on at least one of the bottom package or the second die.

These and other aspects will become more fully understood upon a review of the detailed description, which follows. Other aspects, features, and examples will become apparent to those of ordinary skill in the art upon reviewing the following description of specific exemplary aspects in conjunction with the accompanying figures. While features may be discussed relative to certain examples and figures below, all examples can include one or more of the features discussed herein. In other words, while one or more examples may be discussed as having certain features, one or more of such features may also be used in accordance with the various examples discussed herein. Similarly, while examples may be discussed below as device, system, or method examples, it should be understood that such examples can be implemented in various devices, systems, and methods.

### BRIEF DESCRIPTION OF THE DRAWINGS

FIG. 1 is a diagram depicting an apparatus employing a system-on-chip (SoC) according to some aspects of the present disclosure.

FIG. 2 is a diagram depicting an exemplary package-to-package (PoP) design with an asymmetrical memory interface interconnect according to some aspects of the present disclosure.

FIG. 3 is a diagram depicting a top view of a PoP design with an asymmetrical memory interface interconnect according to some aspects of the present disclosure.

FIG. 4 is a diagram depicting a physical layer (PHY) floor plan of a memory interface of a PoP design according to some aspects of the present disclosure.

FIG. 5 is a diagram depicting a first mapping between memory PHY blocks of an SoC package and memory channels of a memory package in a PoP design according to some aspects of the present disclosure.

FIG. 6 is a diagram depicting a second mapping between memory PHY blocks of an SoC package and memory channels of a memory package in a PoP design according to some aspects of the present disclosure.

FIG. 7 is a diagram illustrating an exemplary method for fabricating a PoP semiconductor device according to some aspects.

FIG. 8 is a diagram illustrating another exemplary method for fabricating a PoP semiconductor device according to some aspects.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

Several aspects of the present disclosure will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, firmware, or any combination thereof. Whether such elements are implemented as hardware or software depends upon the particular application and design constraints imposed on the overall system.

While aspects and examples are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip examples and other non-module-component-based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for the implementation and practice of described examples. It is intended that innovations described herein may be practiced in a wide variety of devices, chip-level components, systems, distributed arrangements, end-user devices, etc., of varying sizes, shapes, and constitution.

Conventional package-on-package (PoP) designs for semiconductor devices can employ a symmetrical ball-out layout for interconnection between the memory and logic packages. A PoP design vertically stacks two or more independently packaged integrated circuits on top of each other in a single package, and use physical electrical connections (e.g., solder balls and connectors) to enable communication between the independent packages. This symmetry can lead to suboptimal routing of high-speed memory interfaces, such as Low Power Double Data Rate (LPDDR) memory interface, particularly in multi-channel configurations. The LPDDR standards are published and maintained by the Joint Electron Device Engineering Council (JEDEC) Solid State Technology Association. The increased routing complexity can result in longer signal paths, higher impedance mismatches, and reduced overall performance. Typical PoP designs also lack efficient thermal management solutions, as they typically rely on passive heat dissipation through the package substrate or external heat sinks. This can result in thermal hotspots, particularly in high-performance applications where both the SoC and memory generate significant heat, ultimately impacting reliability and performance. The z-height of conventional PoP packages is often a critical limitation in mobile devices. As device form factors become thinner, reducing the package height without compromising functionality or performance becomes increasingly challenging.

Aspects of the disclosure provide a PoP design with improved routing layout between a top package and a bottom package, in particular with improved memory-processor routing layout, in particular, in multi-channel configurations. In some aspects, the PoP can have an asymmetrically placed memory interface interconnect for connecting a memory package to a processor package. The memory interface interconnect can include a ball-out layout that is concentrated on one lateral side of the memory package and/or processor package. In some aspects, the PoP design can include a heat slug on the processor package to provide improved thermal management. The disclosed PoP design can optimize memory interface routing, enhance thermal management, and achieve a more competitive form factor.

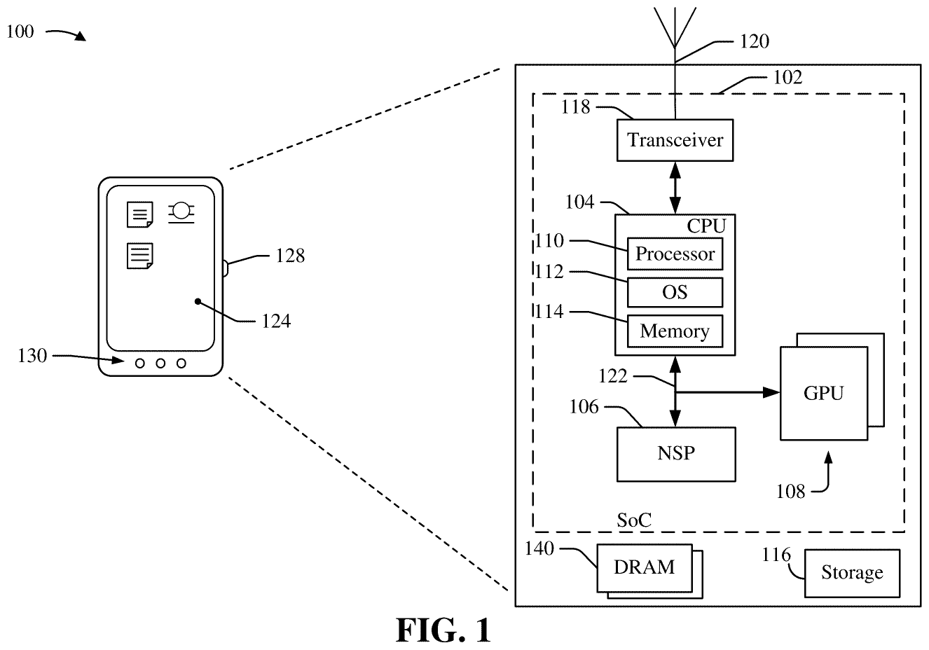

FIG. 1 is a diagram depicting an apparatus employing a system-on-chip (SoC) according to some aspects. In one example, the apparatus 100 may include a radio communication device that communicates through a radio frequency (RF) communications transceiver 118 with a radio access network (RAN), a core access network, the Internet and/or another network. The communications transceiver 118 may be embodied in, or operably coupled to an SoC 102 (the former being illustrated). The SoC 102 may include various components including various processing cores (e.g., central processing unit (CPU) 104, network signal processor (NSP) 106, and graphics processing unit (GPU) 108). In one example, the CPU 104 may include one or more processors 110 and memory 114 (e.g., L1 and/or L2 caches or registers, RAM, etc.), and may be controlled by an operating system 112 that is loaded from internal or external storage as data and instructions that are executable by the processor 110. The apparatus 100 may further include a local storage 116, which can be used to maintain operational parameters and other information (e.g., database) used to configure and operate the apparatus 100. The local storage 116 may be implemented as a set of registers, or may be implemented in flash memory, magnetic media, non-volatile or persistent storage, optical media, tape, soft or hard disk, or the like. The SoC 102 may also be operably coupled to internal and/or external devices such as an antenna 120, a display/user interface 124, operator controls, such as buttons 128, 130, and other components.

A data communication interface (e.g., bus) 122 may be provided to support communication between the various components 104, 106, 108, and/or one or more peripherals (not shown). The data communication interface 122 may be operated in accordance with standard protocols defined for interconnecting certain components of mobile devices. For example, there may be multiple types of interfaces defined for communications between CPU 104, a user interface, and camera components of a mobile device.

In some aspects, the apparatus 100 includes one or more dynamic random access memories (DRAMs) 140, which can be used to store the data or program code used by the SoC 102. In some examples, the DRAM can include low-power double data rate (LPDDR) memory. In some aspects, the DRAM 140 and the SoC 102 can be implemented as different packages of a package-on-package (PoP) configuration. PoP involves stacking two or more fully encapsulated packages on top of each other. Each package typically serves a distinct function, such as a processor in the lower package and memory in the upper package. PoP packages are interconnected using external interconnects, such as solder balls or wire bonding. For example, the DRAM 140 can be included in a memory package stacked on top of a processor package that includes the SoC 102. In some aspects, the PoP may have an asymmetrical memory interface interconnect to provide optimal memory interface routing between the memory package and the processor package. For example, the memory interface interconnect may be asymmetrical with respect to a mirror axis of the PoP. For example, one lateral half may contain more contacts than the other half. In other examples, the apparatus 100 can use other PoP designs that use an asymmetrical interconnect between components that are shown in FIG. 1.

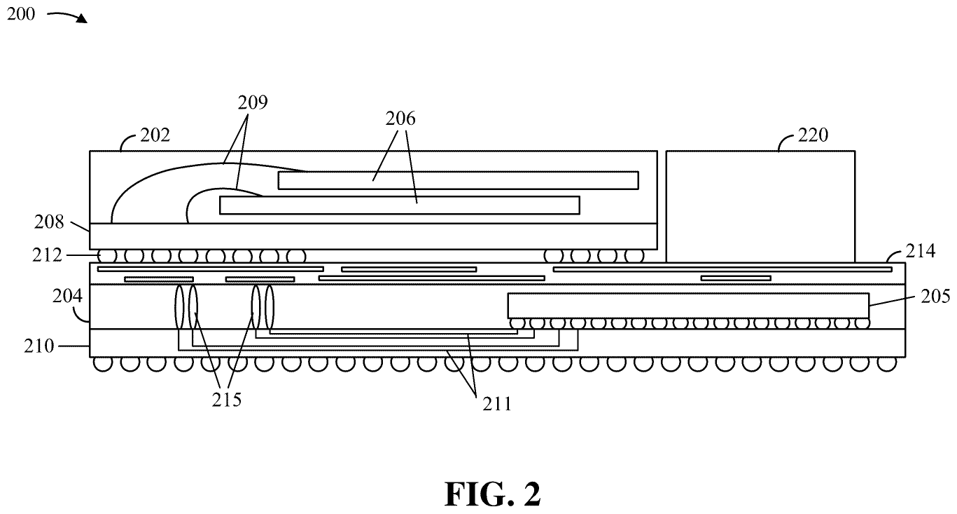

FIG. 2 is a block diagram depicting an exemplary PoP design with an asymmetrical memory interface interconnect according to some aspects. A PoP 200 can include a top package 202 stacked on a bottom package 204. In some aspects, the top package 202 can be a memory package, and the bottom package 204 can be a processor package. For example, the memory package can include DRAM (e.g., LPDDR), and the processor package can include a processor (e.g., SoC die 205). The PoP 200 can be used to implement the SoC and DRAM described above in relation to FIG. 1. The memory package can include one or more memory dies 206 that can be connected to a substrate 208 via an electrical connection (e.g., one or more bonding wires 209 and/or solder balls). Similarly, the SoC die 205 can be connected to a substrate 210 via an electrical connection (e.g., substrate routings 211 and/or solder balls). The electrical connection between the stacked packages can be made via solder balls or pads 212 located between the package surfaces. For example, the top surface of the bottom package can include a grid of solder pads to accommodate the solder balls between the packages. In some aspects, the bottom package may have one or more routing layers 214 that connect the solder balls 212 to the die(s) (e.g. SoC die 205) of the bottom package via one or more connectors 215.

In some aspects, the top package is offset from the bottom package such that at least a portion of the top surface of the bottom package 204 is not covered by the top package 202. In particular, at least at portion of the SoC die 205 is not covered by the top package. In the example shown in FIG. 2, the top package is smaller in size than the bottom package, and the top package is offset to one side (left side in FIG. 2) of the bottom package. This offset arrangement can optimize space, memory interface routing, and thermal management of the PoP. For example, the offset PoP stacking allows a heat spreader (e.g., a heatsink or heat slug 220) to be placed on top of the SoC die to dissipate heat generated by the SoC die in the bottom package. Furthermore, the PoP design 200 can simplify the routing and layout of the memory interface (e.g., LPDDR interface) between the memory dies and SoC die.

The PoP design involves stacking two or more independent packages on top of each other. Each package can include one or more dies (e.g., memory dies or logic dies) enclosed with protective encapsulation, and the packages can be connected via external interconnects such as solder balls and/or pads. Different from PoP designs, die-on-die packaging involves stacking bare dies directly on top of each other without individual packaging or encapsulation. The dies can be connected internally through advanced interconnects, such as through-silicon vias (TSVs) or micro-bumps, creating a tightly integrated multi-die package.

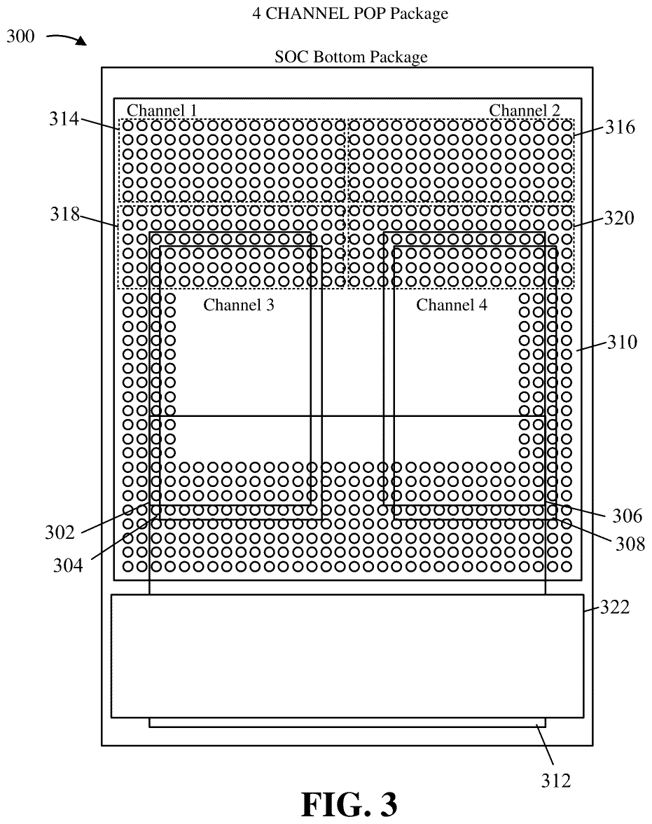

FIG. 3 is a diagram illustrating a top view of a PoP design 300 according to some aspects of the disclosure. The PoP design 300 can be the PoP 200 of FIG. 2. The PoP has a 4-channel memory interface that has an asymmetric design to optimize the memory interface routing between the memory and the SoC. In this example, the top package can include four memory dies 302, 304, 306, and 308 that are offset in position from the SoC die of the bottom package. In some aspects, the PoP may in general have a n-channel memory interface and the top package may include n memory dies, wherein n is an integer number (e.g., a multiple of 2). In some aspects, the substrate 310 of the top package can also be offset (not centered) from the SoC die 312 of the bottom package. Each memory die can be associated with one of four memory interface channels 314, 316, 318, and 320 (e.g., Channels 1, 2, 3, and 4). For example, channel 1 is connected to memory die 1, channel 2 is connected to memory die 2, channel 3 is connected to memory die 3, and channel 4 is connected to memory die 4. The memory interface channels 314, 316, 318, and 320 (e.g., ball-outs for channels 1-4) are asymmetrically concentrated on one side (top side in FIG. 3) of the bottom package. For example, the memory interface channels have an asymmetric ball-out layout (e.g., solder balls or pads), where the ball-out distribution is concentrated on a single lateral side of the package, rather than being evenly distributed across the package surface. In some aspects, the ball-out layout may be asymmetrical with respect to a mirror axis of the top package or the bottom package. For example. one lateral half may contain more contacts (e.g., solder balls or pads) than the other half. In another example, the asymmetric ball-out layout forms clusters of solder balls for each memory interface channel in a single lateral side of the memory package to align with the corresponding memory interface regions of the processor package. The asymmetric memory interface channels placement can reduce signal routing complexity, allowing for shorter and more efficient memory connections (e.g., LPDDR connections) between the SoC die and the memory dies. Further, by concentrating the memory interface channels on a single side, it enables better floor planning of the physical interface layer of the memory interface inside the SoC die.

In some aspects, the offset between the top package and the bottom package allows a heat slug 322 to be placed over a portion of the SoC die 312 to improve thermal dissipation from the SoC die. The SoC die is thermally coupled to the heat slug 322, which provides an efficient path for dissipating heat generated during operation. This design enhances the overall thermal performance compared to PoP designs without such heat dissipation features. Furthermore, the offset placement of the PoP packages results in more efficient use of space that helps to reduce the height of the entire PoP stack. This compact form factor is particularly beneficial for mobile and compact electronic devices.

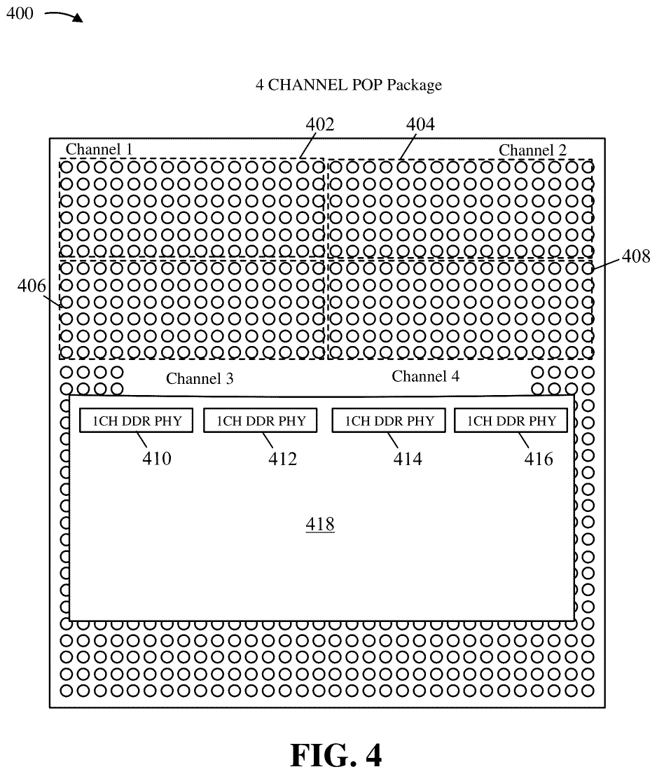

FIG. 4 is a diagram illustrating a physical layer floor plan 400 of a memory interface of a PoP design according to some aspects. The floor plan 400 can be used for the PoP designs described above in relation to FIGS. 2 and 3 or any suitable PoP design. The floor plan can optimize the memory interface between an SoC die of a bottom package and memory dies of a top package for enhanced signal integrity, improved timing, and reduced latency.

In some aspects, one side of the floor plan 400 provides the memory interface (e.g., ball-out areas) for four memory interface channels 402, 404, 406, and 408 (channels 1, 2, 3, and 4). For example, the memory interface channels may include four LPDDR channels. The memory interface channels are placed asymmetrically in the top package relative to the SoC package, with all memory interface channels concentrated on one side (top side in FIG. 4) of the top package. This arrangement can optimize (e.g., minimize) the routing distance between the memory interface channels and the memory physical interface (PHY) blocks 410, 412, 414, and 416 of the SoC die 418. Each memory interface channel can correspond to a dedicated PHY block, which are located strategically on one side of the SoC die 418, near the memory channel ball-outs of the memory dies. This configuration enables optimized signal routing, resulting in better overall signal integrity and performance for high-speed memory communication (e.g., LPDDR).

For example, the SoC die floor plan shows the placement of the four memory (e.g., LPDDR) PHY blocks along one side of the SoC die 418 facing the memory interface ball-outs of the memory dies. In some aspects, the SoC may in general have n memory PHY blocks, wherein n is an integer number (e.g., a multiple of 2). Placing these PHY blocks close to the memory interface channels 402, 404, 406 and 408 allows for highly efficient routing paths, reducing timing mismatches, crosstalk, and routing congestion. This PHY layout also can enhance the timing and layout flexibility for the PHY blocks within the SoC die, thereby improving internal memory interface performance metrics, such as latency and power efficiency. Overall, this asymmetric memory interface design approach can improve the thermal, electrical, and mechanical performance of the PoP design compared to PoP configurations using symmetrical memory interface layout. For example, some previous designs may place memory interface PHY blocks on opposite sides of the SoC die, thus complicating the routing between the SoC die and memory dies.

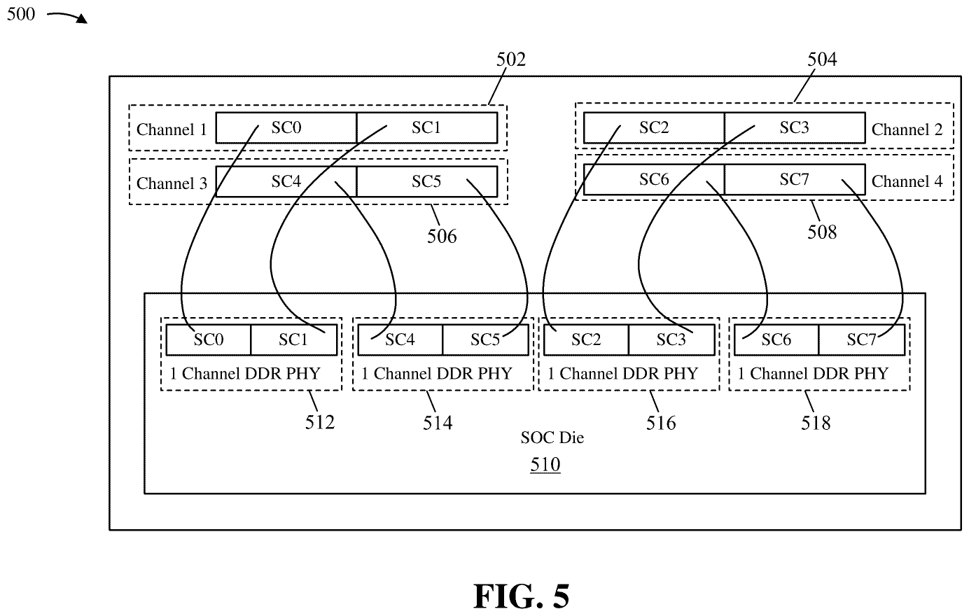

FIG. 5 is a diagram illustrating a first mapping 500 between memory PHY blocks of an SoC package and memory channels of a memory package in a PoP design according to some aspects. The logical mapping can be used in the PoP designs described above in relation to FIGS. 2-4 or any PoP designs. A memory channel (e.g., channel interfaces 502, 504, 506, and 508) is an independent pathway that connects an SoC die 510 to one or more memory dies. Each channel (e.g., channels 1, 2, 3, and 4) can operate independently, allowing for parallel data transfer. A PHY block (e.g., PHY blocks 512, 514, 516, and 518) is the physical interface on the SoC that handles the electrical signaling to and from the memory dies. It can include circuitry for data transmission, reception, and timing control. The PHY block translates logical memory operations from the SoC 510 into electrical signals that the memory dies can understand and vice versa.

In one aspect, the memory package has four memory channel interfaces (channel interfaces 502, 504, 506, and 508). However, in other examples the memory package may in general have n-channel memory interfaces, wherein n is an integer number, preferably a multiple of 2. A memory channel interface can include sub-channels to improve memory access efficiency, bandwidth, and parallelism. Sub-channels provide more granular control over memory operations, enabling better utilization of the memory system's resources. In one example, a first memory interface channel 502 can include two sub-channels SC0 and SC1, a second memory interface channel 504 can include two sub-channels SC2 and SC3, a third memory interface channel 506 can include two sub-channels SC4 and SC5, and a fourth memory interface channel 508 can include two sub-channels SC6 and SC7. The first mapping 500 demonstrates how the memory PHY blocks (e.g., DDR PHY) within the SoC 510 are assigned to the sub-channels of the memory interface channels (e.g., LPDDR memory channels). Each memory PHY block is responsible for managing the signals of a specific memory channel. In this example, each PHY block is assigned to the sub-channels of the same memory channel.

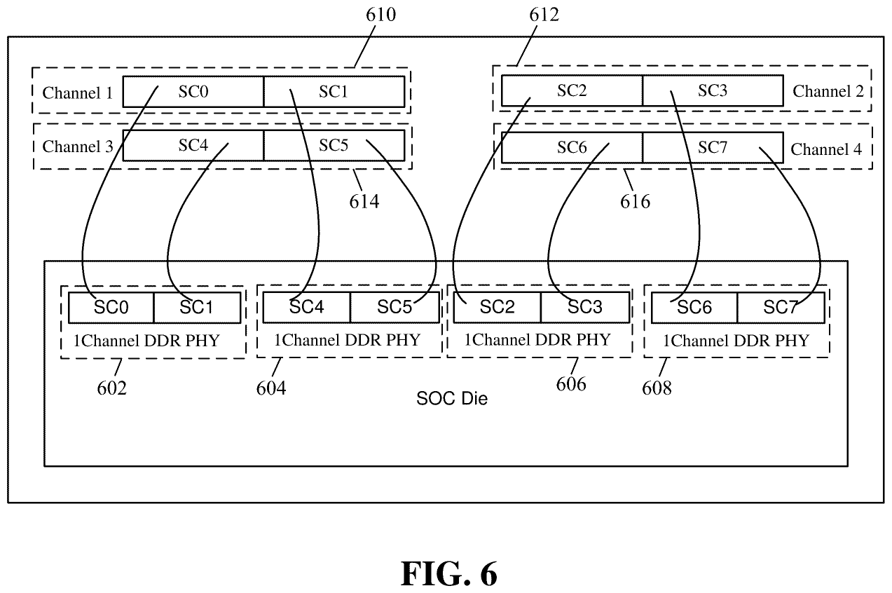

FIG. 6 is a diagram illustrating a second mapping 600 between memory PHY blocks of an SoC package and memory channels of a memory package in a PoP design according to some aspects. The memory channel mapping can be used in the PoP designs described above in relation to FIGS. 2-4 or any PoP designs. The second mapping 600 is different from the first mapping 500 example in that each memory PHY block (e.g., PHY blocks 602, 604, 606, and 608) of the SoC die is mapped to multiple memory interface channels 610, 612, 614, and 616. In one example, a first memory PHY block 602 maps to a sub-channel SC0 of a first memory interface channel 610 and a sub-channel SC4 of a third memory interface channel 614, a second memory PHY block 604 maps to a sub-channel SC1 of the first memory interface channel 610 and a sub-channel SC5 of the third memory interface channel 614, a third memory PHY block 606 maps to a sub-channel SC2 of a second memory interface channel 612 and a sub-channel SC6 of a fourth memory interface channel 616, and a fourth memory PHY block 608 maps to a sub-channel SC3 of the second memory interface channel 612 and a sub-channel SC7 of the fourth memory interface channel 616. In this example, each memory PHY block is mapped to sub-channels of different memory interface channels to optimize signal routing between the SOC die and the memory dies.

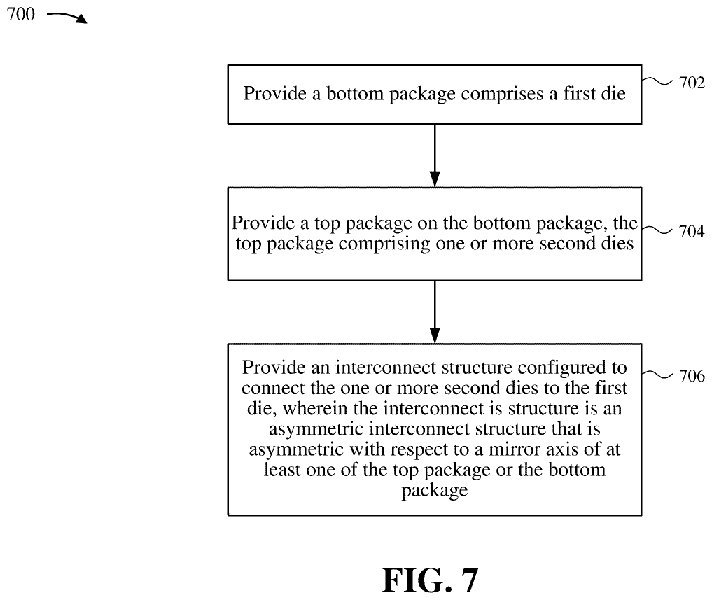

FIG. 7 is a diagram illustrating an exemplary method 700 for fabricating a PoP semiconductor device according to some aspects. As described below, some or all illustrated features may be omitted in a particular implementation within the scope of the present disclosure, and some illustrated features may not be required for implementation of all embodiments. In some examples, the method 700 may be used to fabricate the PoP devices described above in relation to FIGS. 2-6.

At 702, the method includes a process of providing a bottom package including a first die (e.g., an SoC die). For example, the bottom package can be any of the bottom packages described above in relation to FIGS. 2-6. In one example, the SoC die may correspond to the SoC 102 of FIG. 1. At 704, the method includes a process of providing a top package on the bottom package. The top package can include one or more second dies (e.g., one or more memory dies). The one or more memory dies can be any of the memory dies described above in relation to FIGS. 2-6. In one example, the memory dies may correspond to the DRAM(s) 140 of FIG. 1. At 706, the method includes a process of providing an interconnect structure configured to connect the one or more second dies (e.g., memory dies) to the first die (e.g., SoC die). The interconnect structure can be an asymmetric interconnect structure that is asymmetric with respect to a mirror axis of the top package or the bottom package. For example, the interconnect structure can be asymmetrically concentrated on a single lateral side of the top package for optimizing memory interface routing between the SoC die and the one or more memory dies. Optimizing the memory interface routing can reduce the length and complexity of the routing between the packages. The interconnect can include a plurality of solder balls and/or solder pads for connecting the one or more memory dies to the SoC die.

In some aspects, the SoC die includes a plurality of memory PHY blocks (e.g., PHY blocks 410, 412, 414, and 416 of FIG. 4) aligned in position with the ball-out layout to optimize signal integrity and latency. For example, the PHY blocks are aligned or arranged on the same side of the SoC die facing the ball-out of the memory interface. In some aspects, each memory die can include a memory channel connected to a corresponding section (e.g., memory interfaces 314, 316, 318, and 320 of FIG. 3) of the ball-out layout. In some aspects, the memory channel can include a LPDDR memory channel that is subdivided into at least two sub-channels (e.g., SC0, SC1, SC2, SC3, SC4, SC5, SC6, and SC7 of FIGS. 5 and 6). In some aspects, the at least two sub-channels of the same memory channel can be connected to different PHY blocks. In some aspects, the PoP semiconductor device can include a heat slug (heatsink 220 of FIG. 2) thermally coupled to the SoC die for dissipating heat generated during operation. The heat slug and the top package respectively cover different areas of the SoC die. In some aspects, the top package can include one or more bond wires on a same side of the memory dies to connect the memory dies to a substrate that is aligned in location to the memory interface ball-out.

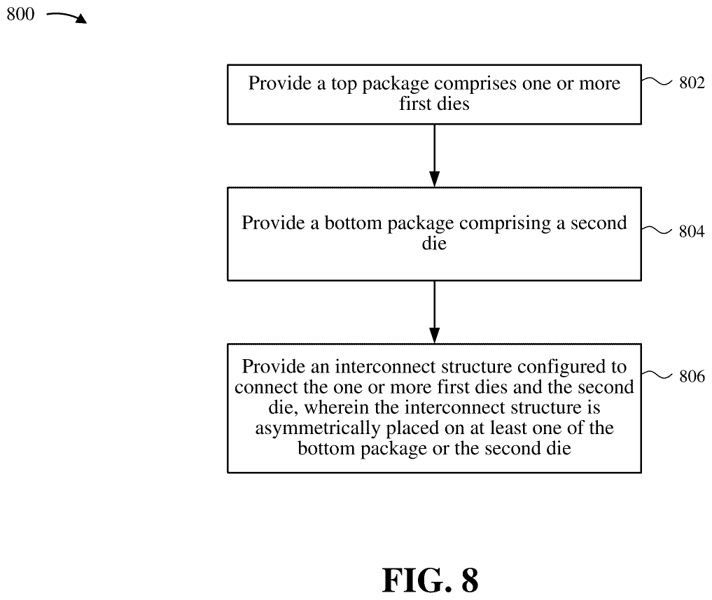

FIG. 8 is a diagram illustrating an exemplary method 800 for fabricating a PoP semiconductor device according to some aspects. As described below, some or all illustrated features may be omitted in a particular implementation within the scope of the present disclosure, and some illustrated features may not be required for implementation of all embodiments. In some examples, the method 800 may be used to fabricate the PoP devices described above in relation to FIGS. 2-6.

At 802, the method includes a process of providing a top package including one or more first die (e.g., one or more memory dies). For example, the top package can be any of the top packages described above in relation to FIGS. 2-6. At 804, the method includes a process of providing a bottom package. The bottom package can include a second die (e.g., SoC die). The one or more memory dies may be any of the memory dies described above in relation to FIGS. 2-6. The SoC die may correspond to the SoC 102 of FIG. 1. In one example, the memory dies may correspond to the DRAM(s) 140 of FIG. 1. At 806, the method further includes a process of providing an interconnect structure configured to connect the one or more first dies (e.g., memory dies) and the second die (e.g., SoC die). The interconnect structure can be asymmetrically placed on at least one of the bottom package or the second die.

For example, the interconnect structure can be asymmetrically concentrated on a single lateral side of the top package for optimizing memory interface routing between the SoC die and the one or more memory dies. Optimizing the memory interface routing can reduce the length and complexity of the routing between the packages. The interconnect can include a plurality of solder balls and/or solder pads for connecting the one or more memory dies to the SoC die.

The following provides an overview of aspects of the present disclosure:
Aspect 1: A package-on-package (PoP) semiconductor device, comprising: a bottom package comprises a first die; a top package positioned on the bottom package, the top package comprising one or more second dies; and an interconnect structure comprising a ball-out layout configured to connect the one or more first dies to the second die, wherein the ball-out layout is an asymmetric ball-out layout that is asymmetric with respect to a mirror axis of at least one of the top package or the bottom package.
Aspect 2: The PoP semiconductor device of aspect 1, wherein: the second die comprises a system-on-chip (SoC) die; and the one or more second dies comprise one or more memory dies.
Aspect 3: The PoP semiconductor device of aspect 2, wherein the SoC die comprises a plurality of memory physical layer (PHY) blocks aligned in position with the asymmetric ball-out layout.
Aspect 4: The PoP semiconductor device of aspect 3, wherein the plurality of memory PHY blocks are concentrated on a single lateral side of the SoC die.
Aspect 5: The PoP semiconductor device of any of one or more of aspects 2, 3, and 4, wherein each memory die of the one or more memory dies comprises a memory channel interface connected to a corresponding section of the asymmetric ball-out layout.
Aspect 6: The PoP semiconductor device of aspect 5, wherein the memory channel interface comprises a low-power double data rate (LPDDR) memory channel that is subdivided into at least two sub-channels.
Aspect 7: The PoP semiconductor device of aspect 6, wherein the at least two sub-channels are connected to different PHY blocks of a plurality of memory physical layer (PHY) blocks on the SoC die.
Aspect 8: The PoP semiconductor device of any of one or more of aspects 1, 2, 3, and 4 further comprising: a heat slug thermally coupled to the first die, wherein the heat slug and the top package respectively cover different areas of the first die.
Aspect 9: The PoP semiconductor device of any of one or more of aspects 1, 2, and 3, wherein the top package comprises: one or more memory dies; a substrate; and one or more bond wires at a same lateral side of the one or more memory dies to connect the one or more memory dies to the substrate aligned in location to the asymmetric ball-out layout.
Aspect 10: A semiconductor device, comprising: a top package comprising one or more first dies; a bottom package comprising a second die; and an interconnect structure configured to connect the one or more first dies and the second die, wherein the interconnect structure is asymmetrically placed on at least one of the bottom package or the second die.
Aspect 11: The semiconductor device of aspect 10, wherein: the top package comprises one or more memory dies, each memory die configured to operate as a memory channel of a plurality of memory channels; the bottom package comprises a processor die with a plurality of memory physical layer (PHY) blocks corresponding to the plurality of memory channels; and the interconnect structure is configured to connect the plurality of memory PHY blocks and the plurality of memory channels.
Aspect 12: The semiconductor device of aspect 11, wherein the plurality of memory PHY blocks are positioned on the same side of the processor die corresponding to the plurality of memory channels.
Aspect 13: The semiconductor device of any of one or more of aspects 11 and 12, wherein the top package is offset from the bottom package such that a top surface of the bottom package corresponding to the processor die is not covered by the top package.
Aspect 14: The semiconductor device of aspect 13, further comprising a heat slug placed on the top surface of the bottom package.
Aspect 15: The semiconductor device of any of one or more of aspects 11 and 12, wherein the interconnect structure comprises a plurality of solder balls connected to the plurality of memory channels.
Aspect 16: The semiconductor device of aspect 15, further comprising a routing layer on the bottom package to connect the processor die to the plurality of solder balls.
Aspect 17: The semiconductor device of aspect 15, wherein the plurality of solder balls are located at a same side of the one or more memory dies.
Aspect 18: The semiconductor device of aspect 15, wherein the plurality of solder balls comprises a plurality of groups of solder balls, each group of the solder balls corresponding to one of the plurality of memory channels.
Aspect 19: The semiconductor device of any of one or more of aspects 11 and 12, wherein the one or more memory dies are wire-bonded to a substrate within the top package.
Aspect 20: The semiconductor device of any of one or more of aspects 11 and 12, wherein the one or more memory dies comprise a plurality of low-power double data rate (LPDDR) memory dies configured to operate in a multi-channel configuration.
Aspect 21: The semiconductor device of aspect 11, wherein the interconnect structure comprises a plurality of electrical connection points arranged in a non-uniform distribution, with a majority of the plurality of electrical connection points concentrated in a predefined region of the top package, rather than evenly distributed across a bottom surface of the top package.
Aspect 22: A method for configuring a package-on-package (PoP) semiconductor device, comprising: providing a bottom package comprises a first die; providing a top package positioned on the bottom package, the top package comprising one or more second dies; and providing an interconnect structure configured to connect the one or more second dies to the first die, wherein the interconnect structure is an asymmetric interconnect structure that is asymmetric with respect to a mirror axis of at least one of the top package or the bottom package.
Aspect 23: The method of aspect 22, wherein: the bottom package comprises a system-on-chip (SoC) die; the top package comprises one or more memory dies; and the interconnect structure is configured to connect the one or more memory dies to the SoC die.
Aspect 24: The method of aspect 23, further comprising: providing a heat slug thermally coupled to the SoC die, wherein the heat slug and the top package respectively cover different areas of the SoC die.
Aspect 25: The method of any of one or more of aspects 23 and 24, wherein the interconnect structure comprises a plurality of solder balls connected to a plurality of memory channels of the one or more memory dies.
Aspect 26: The method of aspect 25, wherein the plurality of solder balls are located at a same side of the one or more memory dies.
Aspect 27: The method of aspect 26, wherein the plurality of solder balls comprises a plurality of groups of solder balls, each group of the solder balls corresponding to one of the plurality of memory channels.
Aspect 28: A method of configurating a semiconductor device, the method comprising: providing a top package comprising one or more first dies; providing a bottom package comprising a second die; and an interconnect structure configured to connect the one or more first dies and the second die, wherein the interconnect structure is asymmetrically placed on at least one of the bottom package or the second die.
Aspect 29: The method semiconductor device of aspect 28, wherein: the top package comprises one or more memory dies, each memory die configured to operate as a memory channel of a plurality of memory channels; the bottom package comprises a processor die with a plurality of memory physical layer (PHY) blocks corresponding to the plurality of memory channels; and the interconnect structure is configured to connect the plurality of memory PHY blocks and the plurality of memory channels.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in FIGS. 1-8 may be rearranged and/or combined into a single component, step, feature or function or embodied in several components, steps, or functions. Additional elements, components, steps, and/or functions may also be added without departing from novel features disclosed herein. The apparatus, devices, and/or components illustrated in FIG. 1-8 may be configured to perform one or more of the methods, features, or steps described herein. The novel algorithms described herein may also be efficiently implemented in software and/or embedded in hardware.

Any reference to an element herein using a designation e.g., “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A package-on-package (PoP) semiconductor device, comprising:
a bottom package comprising a first die;
a top package positioned on the bottom package, the top package comprising one or more second dies; and
an interconnect structure comprising a ball-out layout configured to connect the one or more second dies to the first die, wherein the ball-out layout is an asymmetric ball-out layout that is asymmetric with respect to a mirror axis of at least one of the top package or the bottom package.

2. The PoP semiconductor device of claim 1, wherein:
the first die comprises a system-on-chip (SoC) die; and
the one or more second dies comprises one or more memory dies.

3. The PoP semiconductor device of claim 2, wherein the SoC die comprises a plurality of memory physical layer (PHY) blocks aligned in position with the asymmetric ball-out layout.

4. The PoP semiconductor device of claim 3, wherein the plurality of memory PHY blocks are concentrated on a single lateral side of the SoC die.

5. The PoP semiconductor device of claim 2, wherein each memory die of the one or more memory dies comprises a memory channel interface connected to a corresponding section of the asymmetric ball-out layout.

6. The PoP semiconductor device of claim 5, wherein the memory channel interface comprises a low-power double data rate (LPDDR) memory channel that is subdivided into at least two sub-channels.

7. The PoP semiconductor device of claim 6, wherein the at least two sub-channels are connected to different PHY blocks of a plurality of memory physical layer (PHY) blocks on the SoC die.

8. The PoP semiconductor device of claim 1, further comprising:
a heat slug thermally coupled to the first die, wherein the heat slug and the top package respectively cover different areas of the first die.

9. The PoP semiconductor device of claim 1, wherein the top package comprises:
one or more memory dies;
a substrate; and
one or more bond wires at a same lateral side of the one or more memory dies to connect the one or more memory dies to the substrate aligned in location to the asymmetric ball-out layout.

10. A semiconductor device, comprising:
a top package comprising one or more first dies;
a bottom package comprising a second die; and
an interconnect structure configured to connect the one or more first dies and the second die,
wherein the interconnect structure is asymmetrically placed on at least one of the bottom package or the second die.

11. The semiconductor device of claim 10, wherein:
the top package comprises one or more memory dies, each memory die configured to operate as a memory channel of a plurality of memory channels;
the bottom package comprises a processor die with a plurality of memory physical layer (PHY) blocks corresponding to the plurality of memory channels; and
the interconnect structure is configured to connect the plurality of memory PHY blocks and the plurality of memory channels.

12. The semiconductor device of claim 11, wherein the plurality of memory PHY blocks are positioned on the same side of the processor die corresponding to the plurality of memory channels.

13. The semiconductor device of claim 11, wherein the top package is offset from the bottom package such that a top surface of the bottom package corresponding to the processor die is not covered by the top package.

14. The semiconductor device of claim 13, further comprising a heat slug placed on the top surface of the bottom package.

15. The semiconductor device of claim 11, wherein the interconnect structure comprises a plurality of solder balls connected to the plurality of memory channels.

16. The semiconductor device of claim 15, further comprising a routing layer on the bottom package to connect the processor die to the plurality of solder balls.

17. The semiconductor device of claim 15, wherein the plurality of solder balls are located at a same side of the one or more memory dies.

18. The semiconductor device of claim 15, wherein the plurality of solder balls comprises a plurality of groups of solder balls, each group of the solder balls corresponding to one of the plurality of memory channels.

19. The semiconductor device of claim 11, wherein the one or more memory dies are wire-bonded to a substrate within the top package.

20. The semiconductor device of claim 11, wherein the one or more memory dies comprise a plurality of low-power double data rate (LPDDR) memory dies configured to operate in a multi-channel configuration.

21. The semiconductor device of claim 11, wherein the interconnect structure comprises a plurality of electrical connection points arranged in a non-uniform distribution, with a majority of the plurality of electrical connection points concentrated in a predefined region of the top package, rather than evenly distributed across a bottom surface of the top package.

22. A method for configuring a package-on-package (PoP) semiconductor device, comprising:
providing a bottom package comprising a first die;
providing a top package positioned on the bottom package, the top package comprising one or more second dies; and
providing an interconnect structure configured to connect the one or more second dies to the first die,
wherein the interconnect structure is an asymmetric interconnect structure that is asymmetric with respect to a mirror axis of at least one of the top package or the bottom package.

23. The method of claim 22, wherein:
the bottom package comprises a system-on-chip (SoC) die;
the top package comprises one or more memory dies; and
the interconnect structure is configured to connect the one or more memory dies to the SoC die.

24. The method of claim 23, further comprising:
providing a heat slug thermally coupled to the SoC die, wherein the heat slug and the top package respectively cover different areas of the SoC die.

25. The method of claim 23, wherein the interconnect structure comprises a plurality of solder balls connected to a plurality of memory channels of the one or more memory dies.

26. The method of claim 25, wherein the plurality of solder balls are located at a same lateral side of the one or more memory dies.

27. The method of claim 26, wherein the plurality of solder balls comprises a plurality of groups of solder balls, each group of the solder balls corresponding to one of the plurality of memory channels.

28. A method of configurating a semiconductor device, the method comprising:
providing a top package comprising one or more first dies;
providing a bottom package comprising a second die; and
an interconnect structure configured to connect the one or more first dies and the second die,
wherein the interconnect structure is asymmetrically placed on at least one of the bottom package or the second die.

29. The method of claim 28, wherein:
the top package comprises one or more memory dies, each memory die configured to operate as a memory channel of a plurality of memory channels;
the bottom package comprises a processor die with a plurality of memory physical layer (PHY) blocks corresponding to the plurality of memory channels; and
the interconnect structure is configured to connect the plurality of memory PHY blocks and the plurality of memory channels.
